(19) United States
(12) Patent Application Publication
(10) Pub. No.: US 2013/0002299 A1
(43) Pub. Date: Jan. 3, 2013

(54) LOGIC LEVEL TRANSLATOR AND ELECTRONIC SYSTEM

(75) Inventors: CHUN-LUNG HUNG, Tu-Cheng (TW); KUO-PIN LIN, Tu-Cheng (TW); DONG-LIANG REN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/310,719

(22) Filed: Dec. 3, 2011

(30) Foreign Application Priority Data
Jun. 29, 2011 (CN) 201110179292.6

(51) Int. Cl. H03K 19/094; H03K 19/0175

(52) U.S. Cl. 326/68; 326/63

(57) ABSTRACT

A logical level translator includes a first reference voltage provider, a second reference voltage provider, and a switching circuit. The first reference voltage provider provides a first reference voltage signal with a first logic level to a first connection terminal. The second reference voltage provider provides a second reference voltage signal with a second logic level to a second connection terminal. The switching circuit switches on a connection between the first connection terminal and the second connection terminal when a digital signal input to the first connection terminal or the second connection terminal is a logic high level signal. Then switches off the connection between the first connection terminal and the second connection terminal when the digital signals is a logic low level signal.

### BACKGROUND

1. Technical Field

The present disclosure relates to logic level translation, and more particularly, to a logic level translator and an electronic system using the logic level translator.

2. Description of Related Art

In digital circuits, a logic level is defined to represent a signal state. Logic levels are usually represented by a voltage difference between a signal and a common reference (e.g., a ground level). In binary logic, two levels (namely, logic high level and logic low level) generally correspond to binary digits of 1 and 0, respectively. In detail, the logic high level represents the binary digit of 1, and the logic low level represents a binary digit of 0. Signals with one of these two levels can be used in Boolean logic for digital circuit design or analysis.

Transistor-transistor logic (TTL) is one of dominant standards for logic circuits, which is defined as operating at a logic level of 5V (volts). However, the increasing complexity of modern electronic systems has led to lower voltage logic, for example, low voltage TTL or complementary metal oxide semiconductor (CMOS) is defined as operating at a different logic level of 3.3V (volts). This difference between two logic levels may cause logic level incompatibility to exist within an electronic system.

Take a liquid crystal display (LCD) as an example, the LCD may include a video driver chip operating at a first logic level of 3.3V and a high definition multimedia interface (HDMI) module operating at a second logic level of 5V. The HDMI module may receive video data from an external video source. The video data received by the HDMI module is transmitted to the video driver chip so that the video driver chip can drive a liquid crystal panel to display corresponding images. However, due to the logic level incompatibility between the video driver chip and the HDMI module, when the video data with the first logic level of 5V are transmitted to the video driver chip operating at the second logic level of 3.3V without any logic level translation, the video driver chip may be burned out by the video data of 5V.

What is needed is to provide a logic level translator for performing logic level translation that will overcome the aforementioned limitations.

### BRIEF DESCRIPTION OF THE DRAWINGS

The components in the drawings are not necessarily drawn to scale, the emphasis instead being placed upon clearly illustrating the principles of at least one embodiment. In the drawings, like reference numerals designate corresponding parts throughout the various views.

FIG. 1 illustrates a block diagram of an electronic system according to an embodiment of the present disclosure, the electronic system including a first digital section, a second digital section and a logic level translator.

FIG. 2 illustrates a circuit configuration of the logic level translator of the electronic system of FIG. 1.

FIG. 3 illustrates waveforms of a first I/O port of the first digital section and a second I/O port of the second digital section of the electronic system of FIG. 1.

### DETAILED DESCRIPTION

Reference will now be made to the drawings to describe specific exemplary embodiments of the present disclosure in detail.

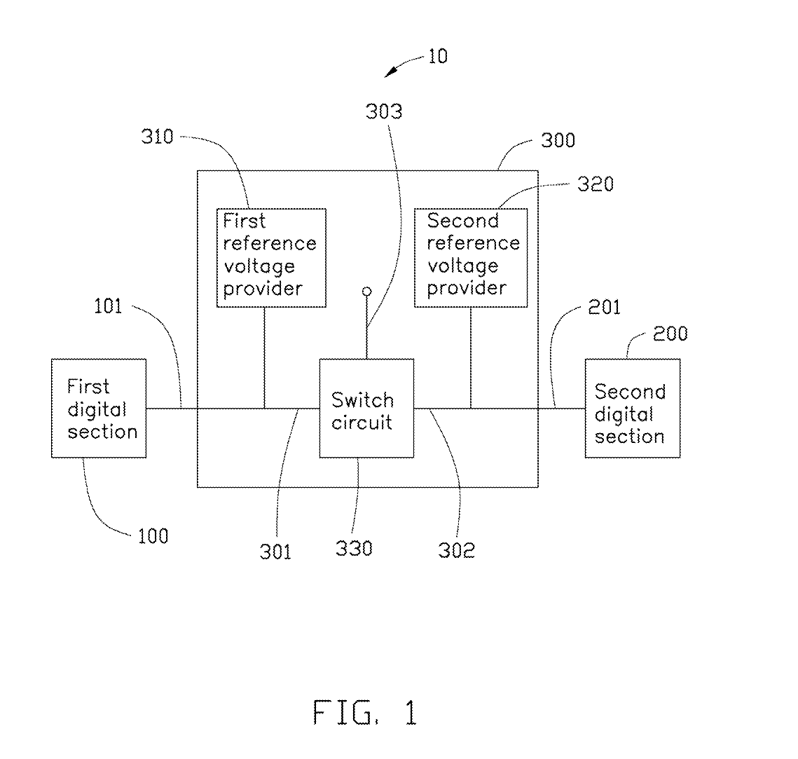

FIG. 1 illustrates a block diagram of an electronic system 10 according to an embodiment of the present disclosure. The electronic system 10 may be included in a consumer electronic device such as a television, a notebook computer, a display monitor, a mobile phone, for example. The electronic system 10 includes a first digital section 100, a second digital section 200, and a logic level translator 300 electrically coupled between the first digital section 100 and the second digital section 200.

The first digital section 100 may be a first logic function module of the electronic system 10, such as a video driver chip of a display monitor or a television, a south-bridge or north-bridge chip of a notebook computer, a communication chip of a mobile phone, for example. The first digital section 100 may include a first input/output (I/O) port 101 operating at a first logic level, e.g., about 3.3V. Correspondingly, signals input to or output from the first I/O port 101 of the first digital section 100 are digital signals at the first logic level of 3.3V.

The second digital section 200 may be a second logic function module of the electronic system 10, such as an HDMI module or other digital interface module. The second digital section 200 may include a second I/O port 201 operating at a second logic level, e.g., about 5V. Correspondingly, signals output from or input to the second I/O port 201 of the second digital section 200 are digital signals at the second logic level of 5V.

In one embodiment, the first digital section 100 and the second digital section 200 may communicate with each other via an inter-integrated circuit (I2C) bus, and the logic level translator 300 is electrically configured within the I2C bus.

The logic level translator 300 is used to translate different logic levels between the first digital section 100 and the second digital section 200. The translation of logic levels is done such that communication between the first digital section 100 and the second digital section 200 can be achieved even though the first digital section 100 and the second digital section 200 operate at different logic levels.

The logic level translator 300 may include a first reference voltage provider 310, a second reference voltage provider 320, and a switch circuit 330. The first reference voltage provider 310 provides a first reference voltage with the first logic level of 3.3V, and is electrically coupled to the first I/O port 101 of the first digital section 100. The second reference voltage provider 320 provides a second reference voltage with the second logic level of 5V, and is electrically coupled to the second I/O port 201 of the second digital section 200. The switch circuit 330 may include a first connection terminal 301, a second connection terminal 302, and a control terminal 303. The first connection terminal 301 and the second connection terminal 302 are respectively electrically coupled to the first I/O port 101 and the second I/O port 201. The control terminal 303 is electrically coupled to the first reference voltage or the second reference voltage. In the illustrated embodiment, the control terminal 303 is electrically coupled to one of the first reference voltage and the second reference voltage having a lower voltage (such as 3.3V).

The switch circuit 300 switches on or switches off a connection between the first connection terminal 301 and the second connection terminal 302 according to a logic level of the signal transmitted between the first I/O port 101 and the second I/O port 201. In this embodiment, when the signal transmitted between the first I/O port 101 and the second I/O port 201 is at a logic high level, e.g., 3.3V or 5V, the connection between the first connection terminal 301 and the second connection terminal 302 are switched off. When the signal transmitted between the first I/O port 101 and the second I/O port 201 is at a logic low level, e.g., at ground level 0V, the connection between the first connection terminal 301 and the second connection terminal 302 are switched on.

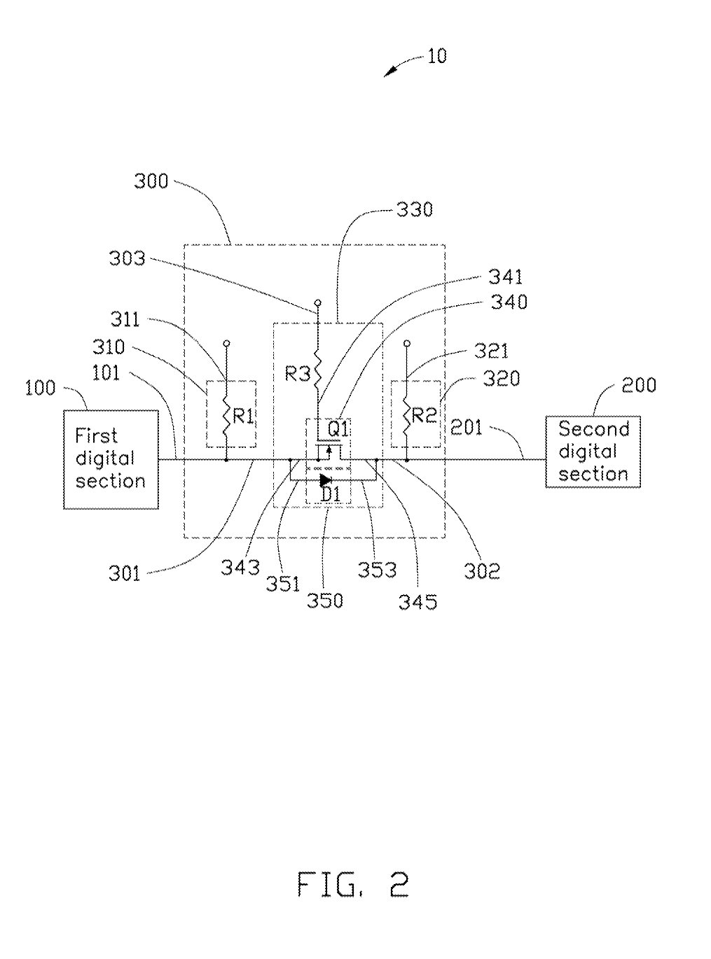

Referring also to FIG. 2, in one embodiment, the first reference voltage provider 310 includes a first reference receiving terminal 311 for receiving the first reference voltage with the first logic level of 3.3V. A first pull-up resistor R1 is electrically coupled between the first reference receiving terminal 311 and the first I/O port 101 of the first digital section 100. The second reference voltage provider 320 includes a second reference receiving terminal 321 for receiving the second reference voltage with the second logic level of 5V, and a second pull-up resistor R2 electrically coupled between the second reference receiving terminal 321 and the second I/O port 201 of the second digital section 200.

The switch circuit 330 includes a first switch element 340 and a second switch element 350. The first switch element 340 may be a n-channel metal oxide semiconductor (NMOS) transistor Q1 including a gate electrode 341 electrically coupled to the control terminal 303 via a third pull-up resistor R3, a source electrode 343 electrically coupled to the first connection terminal 301, and a drain electrode 345 electrically coupled to the second connection terminal 302. The second switch element 350 may be a diode D1 having a positive terminal 351 electrically coupled to the first connection terminal 301, and a negative terminal 353 electrically coupled to the second connection terminal 302.

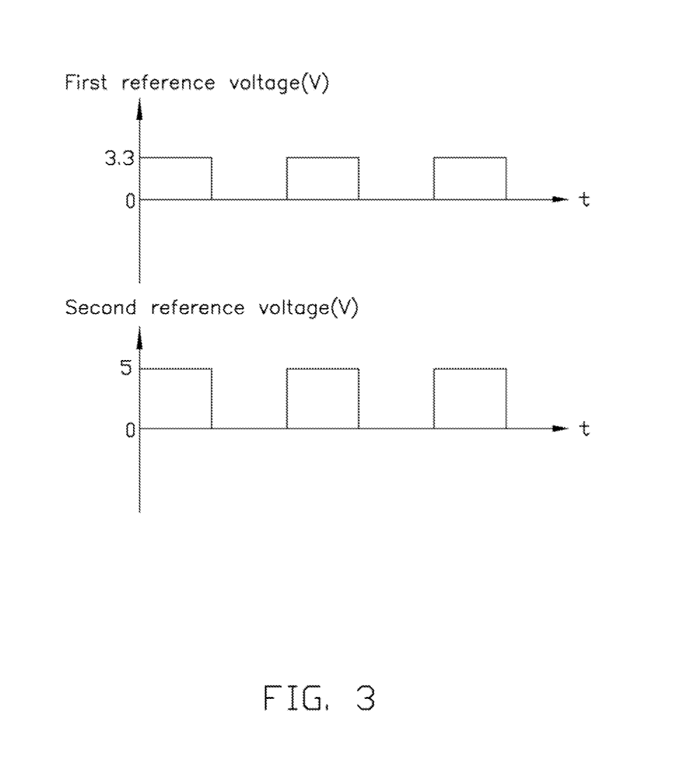

Referring also to FIG. 3, in operation of the electronic system 10, the first digital section 100 and the second digital section 200 may communicate with each other to exchange digital signals. During the signal communication, the logic level translator 300 can perform logic level translation on the digital signals to ensure that digital signals received by a receiver end have logic levels match logic levels of the a transmitter end.

The operation of the electronic system 10 may include the following two modes.

Mode 1: the first digital section 100 serves as a transmitter end and the second digital section 200 serves as a receiver end.

In the mode 1, when the digital signal output by the first I/O port 101 of the first digital section 100 represents binary 0, the digital signal has a logic low level of 0V. Because the gate electrode 341 of the first switch element 340 receives the first reference voltage of 3.3V from the control terminal 303, a voltage difference between the gate electrode 341 and the source electrode 343 is 3.3V, thus the first switch element 340 is switched on. Accordingly, the second I/O port 201 of the second digital section 200 receives the digital signal of 0V from the first I/O port 101 of the first digital section 100 by means of the first switch element 340.

When the digital signal output by the first I/O port 101 of the first digital section 100 represents binary 1, the digital signal has a logic high level of 3.3V. The voltage difference between the gate electrode 341 and the source electrode 343 is 0V, thus the first switch element 340 is switched off. Moreover, the digital signal of 3.3V at the first I/O port 101 also causes the second switch element 350 to be switched off because a voltage difference between the positive terminal 351 and the negative terminal 353 of the second switch element 350 is 3.3V−5V=−1.7V. Since the switching circuit 330 is switched off, a voltage level of the second I/O port 201 of the second digital section 200 is pulled up to the second reference voltage of 5V by the second pull-up resistor R2 of the second reference voltage provider 320. That is, the second digital section 200 receives a digital signal at the logic level of 5V. The logic level translator 300 consequently realizes the logic level translation of the binary 1, with the first logic level of 3.3V to a same binary with the second logic level of 5V.

Mode 2: the first digital section 100 servers as a receiver end and the second digital section 200 servers as a transmitter end.

In the mode 2, when the digital signal output by the second I/O port 201 of the second digital section 200 represents binary 0, the digital signal has a logic low level of 0V. Since the source electrode 343 of the first switch element 340 receives the first reference voltage of 3.3V from the first reference voltage provider 310, the voltage difference between the gate electrode 341 and the source electrode 343 is 0V, and thus the first switch element 340 is still switched off. However, a voltage difference between the positive terminal 351 and the negative terminal 353 of the second switch element 350 is 3.3V, thus the second switch element 350 is switched on. Accordingly, the first I/O port 101 of the first digital section 100 receives the digital signal of 0V from the second I/O port 201 of the second digital section 200 by means of the second switch element 350.

When the digital signal output by the second I/O port 201 of the first digital section represents binary 1, the digital signal has a logic high level of 5V. Since the first reference voltage of 3.3V provided by the first reference voltage provider 310, the voltage difference between the gate electrode 341 and the drain electrode 343 is still 0V, and thus the first switch element 340 is switched off. Moreover, the digital signal of 5V at the second I/O port 201 also causes the second switch element 350 to be switched off because a voltage difference between the positive terminal 351 and the negative terminal 353 of the second switch element 350 is −1.7V. Since the switching circuit 330 is switched off, a voltage level of the first I/O port 101 of the first digital section 100 is pulled up to the first reference voltage of 3.3V by the first pull-up resistor R1 of the second reference voltage provider 310. That is, the second digital section 200 receives a digital signal at the logic level of 3.3V. The logic level translator 300 consequently realizes the logic level translation of the binary 1, with the second logic level of 5V to a same binary with the first logic level of 3V.

As can be seen, due to the logic level translation performed by the logic level translator 300. When the first digital section 100 and the second digital section 200 communicate, it can be ensured that the digital signal received by either the first digital section 100 or the second digital section 200 has a matched logic level of the transmitter end. This can prevent the first digital section 100 and the second digital section 200 from being burned out due to an excessive voltage level, and thus improve reliability of the electronic system.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A logic level translator, comprising
a first reference voltage provider configured for providing a first reference voltage signal with a first logic level to a first connection terminal;
a second reference voltage provider configured for providing a second reference voltage signal with a second logic level to a second connection terminal; and
a switching circuit for switching on a connection between the first connection terminal and the second connection terminal when a digital signal input to the first connection terminal or the second connection terminal is a logic high level signal, and switching off the connection between the first connection terminal and the second connection terminal when the digital signals is a logic low level signal.

2. The logic level translator of claim 1, wherein the switching circuit comprises a metal oxide semiconductor (MOS) transistor comprising a gate electrode receiving the first reference voltage signal, a source electrode electrically coupled to the first connection terminal, and a drain electrode electrically coupled to the second connection terminal.

3. The logic level translator of claim 2, wherein the switching circuit further comprises a diode having a positive terminal electrically coupled to the first connection terminal, and a negative terminal electrically coupled to the second connection terminal.

4. The logic level translator of claim 1, wherein the first reference voltage provider comprises a first reference receiving terminal receiving the first reference voltage signal with the first logic level, and a first pull-up resistor electrically coupled between the first reference receiving terminal and the first connection terminal.

5. The logic level translator of claim 4, wherein the second reference voltage provider comprises a second reference receiving terminal receiving the second reference voltage signal with the second logic level, and a second pull-up resistor electrically coupled between the second reference receiving terminal and the second connection terminal.

6. The logic level translator of claim 1, wherein the first logic level is of about 3.3V and the second logic level is of about 5V.

7. An electronic system, comprising:
a first digital section operating at a first logic level;
a second digital section communicating with the first digital section, the second digital section operating at a second logic level greater than the first logic level; and
a logic level translator connected between the first digital section and the second digital section, and configured for performing logic level translation on digital signals transmitted between the first digital section and the second digital section.

8. The electronic system of claim 7, wherein the logic level translator translates a first digital signal output by the first digital section from the first logic level to the second logic level, and translates a second digital signal output by the second digital section from the second logic level to the first logic level.

9. The electronic system of claim 7, wherein the logic level translator comprises:
a first reference voltage provider configured for providing a first reference voltage signal with the first logic level, the first reference voltage provider being electrically coupled to a first I/O port of the first digital section;
a second reference voltage provider configured for providing a second reference voltage signal with the second logic level, the second first reference voltage provider being electrically coupled to a second I/O port of the second digital section; and
a switching circuit for switching on a connection between the first I/O port and the second I/O port when the digital signals transmitted between the first digital section and the second digital section represent binary 0, and switching off the connection between the first I/O port and the second I/O port of the second digital section when the digital signals represent binary 1.

10. The electronic system of claim 9, wherein the switching circuit comprises a metal oxide semiconductor (MOS) transistor comprising a gate electrode for receiving the first reference voltage signal, a source electrode electrically coupled to the first I/O port, and a drain electrode electrically coupled to the second I/O port.

11. The electronic system of claim 10, wherein the switching circuit further comprises a diode having a positive terminal electrically coupled to the first I/O port, and a negative terminal electrically coupled to the second I/O port.

12. The electronic system of claim 9, wherein the first reference voltage provider comprises a first reference receiving terminal receiving the first reference voltage signal with the first logic level, and a first pull-up resistor electrically coupled between the first reference receiving terminal and the first I/O port.

13. The electronic system of claim 12, wherein the second reference voltage provider comprises a second reference receiving terminal receiving the second reference voltage signal with the second logic level, and a second pull-up resistor electrically coupled between the second reference receiving terminal and the second I/O port.

14. The electronic system of claim 7, wherein the first digital section is a chip and the second digital section is an interface module.

15. The electronic system of claim 14, wherein the first logic level is of about 3.3V and the second logic level is of about 5V.

16. The electronic system of claim 7, wherein the first digital section communicates with the second digital section via an inter-integrated circuit (I2C) bus, and the logic level translator is configured within the I2C bus.

17. An electronic device, comprising:
a first digital section operating at a first logic level;
a second digital section communicating with the first digital section, the second digital section operating at a second logic level greater than the first logic level; and
a logic level translator connected between the first digital section and the second digital section, the logic level translator is configured for translating a first digital signal output by the first digital section from the first logic level to the second logic level, and translating a second digital signal output by the second digital section from the second logic level to the first logic level.

18. The electronic system of claim 17, wherein the logic level translator comprises:
a first reference voltage provider configured for providing a first reference voltage signal with the first logic level, the first reference voltage provider being electrically coupled to a first I/O port of the first digital section;
a second reference voltage provider configured for providing a second reference voltage signal with the second logic level, the second reference voltage provider being electrically coupled to a second I/O port of the second digital section; and
a switching circuit for switching on a connection between the first I/O port and the second I/O port when the digital signals transmitted between the first digital section and the second digital section represent binary 0, and switching off the connection between the first I/O port and the second I/O port of the second digital section when the digital signals represent binary 1.

19. The electronic system of claim 18, wherein the switching circuit comprises a metal oxide semiconductor (MOS) transistor comprising a gate electrode receiving the first reference voltage signal, a source electrode electrically coupled to the first I/O port, and a drain electrode electrically coupled to the second I/O port.

20. The electronic system of claim 19, wherein the switching circuit further comprises a diode comprising a positive terminal electrically coupled to the first I/O port, and a negative terminal electrically coupled to the second I/O port.
